(19) United States
(12) Patent Application Publication
(10) Pub. No.: US 2023/0088793 A1
(43) Pub. Date: Mar. 23, 2023

(54) TRANSITION STRUCTURE BETWEEN TRANSMISSION LINE OF MULTILAYER PCB AND WAVEGUIDE

(71) Applicant: NEXWAVE INC, Daejeon (KR)

(72) Inventor: Jin-Wan JEON, Daejeon (KR)

(73) Assignee: NEXWAVE INC, Daejeon (KR)

(21) Appl. No.: 17/921,441

(22) PCT Filed: Dec. 14, 2021
(86) PCT No.: PCT/KR2021/018930

§ 371 Date: Oct. 26, 2022

(30) Foreign Application Priority Data
Dec. 16, 2020 (KR) 10-2020-0176773

(51) Int. Cl. H01P 5/107; H01P 3/08; H05K 1/02; H05K 1/11

(52) U.S. Cl. CPC H01P 5/107; H01P 3/08; H05K 1/0237; H05K 1/115

(57) ABSTRACT

A transition structure between a transmission line of a multilayer PCB and a waveguide is proposed. The transition structure includes the waveguide comprising an interior space on one side thereof and having an inlet for accommodating a part of a stripline, the transmission line comprising a first ground layer of the multilayer PCB composed of at least two or more dielectric layers, the stripline extending from the transmission line and protruding into the waveguide through the inlet of the waveguide, and a single via hole or a plurality of via holes formed between the first ground layer and a bottommost ground layer, wherein each via hole is positioned at the inlet of the waveguide.

### TECHNICAL FIELD

The present disclosure relates to a structure or a method for transmitting signals by physical coupling between a transmission line of a multilayer PCB and a waveguide in an ultra-high frequency domain such as microwaves or millimeter waves.

The present disclosure relates to a transition structure between a waveguide and a transmission line of a printed circuit board (PCB) such as a microstrip line, a stripline, a coplanar waveguide (CPW), and a coplanar waveguide with ground (CPWG), which transmit signals in a configuration of integrated circuits and systems in the ultra-high frequency domain.

More particularly, the present disclosure relates to a transition structure between a transmission line of a multilayer PCB and a waveguide to which one or more via holes or one or more rows of via holes are applied to specific positions of the multilayer PCB in the structure combining a transmission line of a multilayer PCB and a waveguide in order to effectively propagate signals with low loss between the transmission line such as a microstrip line and the waveguide.

### BACKGROUND ART

As the frequency band of mobile communication increases, a demand for ultra-high frequency integrated circuits is rapidly increasing. Such ultra-high frequency integrated circuits are generally composed of various related power elements such as monolithic microwave integrated circuit (MMIC) elements and electronic devices such as diodes. In addition, the ultra-high frequency integrated circuits may also be composed of passive components and connecting components thereof, which use waveguide components to secure low loss and high performance. Components using such a waveguide structure include various antennas, filters, diplexers, feeding components, and connecting components

That is, usually, in order to achieve an ultra-high frequency integrated circuit at a low cost having low transmission loss, the ultra-high frequency integrated circuit is composed in a fixed form where a transmission line, such as a microstrip line connected from an output terminal of integrated circuits on a printed circuit board (PCB), and waveguides related components are properly combined. the ultra-high frequency integrated circuit is composed in a fixed form where a transmission line, such as a microstrip line connected from an output terminal of integrated circuits on a printed circuit board (PCB), properly combining waveguides related components.

Meanwhile, a waveguide is used for implementing a low-loss, high-performance passive element (e.g., horn antennas, slot antennas, filters, etc.) mainly in an ultra-high frequency band (e.g., a millimeter wave with a frequency of several tens of GHz and the like and with a wavelength in millimeter units). The waveguide transmits electromagnetic wave signals by using a resonance phenomenon due to a physical structure of the waveguide, and is usually in the form of hollow circular or rectangular metallic guides and designed to have a physical size corresponding to the frequency characteristics of corresponding transmitted signals.

Such a waveguide is constructed in an empty rectangular metal block structure filled with air, and provides the lowest dielectric loss and excellent transmission characteristics, thereby being implementable with high performance. However, in order to combine such a waveguide type of components with integrated circuits implemented on the PCB, an additional signal transition structure with transmission lines of the PCB used for transmitting the signals is required as describe above.

That is, it is necessary to have a transition structure in which ultra-high frequency signals are efficiently transmitted, with low loss, to the waveguide from a transmission line (e.g., a microstrip line, a CPW line, a CPWG line, a stripline, etc.) through which the signals are transmitted on the PCB.

Accordingly, a transition structure between a transmission line and a waveguide of a PCB has been developed. As a related art, according to U.S. Pat. No. 6,917,256 (hereinafter referred to as “the related art”), the structure for transferring signals of the transmission line to the waveguide is disclosed. The related art is the structure that is relatively widely applied for signal transfer between the waveguide and the transmission line of the PCB, and is a structure in which signals transmitted to a microstrip transmission line of a PCB are transferred to inside of a waveguide through a strip line extended from a microstrip.

In order to transmit signals of a microstrip transmission line to an exit in a downward direction of a waveguide, there is provided a structure formed in such a way that a predetermined space is left on an upper side opposite to the exit and the waveguide is all blocked. That is, the predetermined space for resonance of the signals should be secured between the transmission line protruding into the waveguide and an upper wall of the waveguide. That is, parameters such as a physical structural design of the transmission line of a PCB and the waveguide through which signals are transferred, a propagation frequency of the ultra-high frequency signals, a size of the structure in which the transmission line is coupled to the inside of the waveguide, material characteristics of a substrate, and the like are all design parameters to reduce loss and the like during signal transition and to ensure good signal transition.

According to the disclosure of the related art, production time and cost may be significantly reduced in comparison with that of an assembling and combining method for reducing transition loss by manually adjusting positions of a tuning screw and the like in a coupling part in a waveguide.

In addition, a part using such a signal transition structure usually corresponds to a front end part of wireless communication, and a power amplifier element and its connected transmission lines are applied thereto. That is, in a case where signal loss in the transition structure is large, outputs of the power amplifier element and the like should be designed and manufactured to be as large as that signal loss and applied accordingly, thereby causing a price increase due to performance increases of the elements and causing a considerable amount of power consumption and heat generation due to power increases of the elements. Accordingly, designing the transition structure to have low loss is a very important factor in the construction of the ultra-high frequency circuit.

Meanwhile, as frequencies are increased compared to that of the related art, the above-described ultra-high frequency electronic circuit becomes very complicated and has to perform various functions, so it becomes difficult to construct and connect the integrated circuit with a single-layer PCB. Accordingly, the ultra-high frequency electronic circuit is being implemented with a multilayer PCB to increase the degree of integration and to perform various functions.

In addition, signal loss due to a substrate material becomes an important problem, and in order to resolve the problem, a substrate made of dielectric materials, such as Teflon with low signal loss, that is different from dielectric materials such as FR4 used in conventionally common integrated circuit boards may also be used. However, such a substrate with the low signal loss has a problem in that a material cost is very high compared to that of a substrate made of a material such as FR4 that is widely and previously used, mechanical properties are poor, and a process of forming a multilayer becomes difficult.

As such, an ultra-high frequency electronic circuit is usually implemented on a multilayer PCB due to the complexity of the circuit and the configuration and the like for implementing various functions. Accordingly, when a multilayer PCB is manufactured, in order to provide a low cost having low loss of multilayer PCB, the multilayer PCB to which heterogeneous dielectric materials rather than one dielectric material are bonded and applied is sometimes used, in a method where only a substrate layer whose transmission loss is important is formed with an expensive material with low loss and the remaining layers are formed with a conventional inexpensive material.

Accordingly, different from the transition structure between the waveguide and the transmission line on the conventional PCB, a new transition structure is required to effectively transmit signals with low loss between a waveguide and a transmission line on such a multilayer PCB or a multilayer PCB composed of heterogeneous substrate materials. Therefore, a transition structure and a method thereof between a transmission line of a multilayer PCB and a waveguide, which is different from a transition structure between a transmission line of the conventional PCB and a waveguide, should be newly considered.

### DISCLOSURE

### Technical Problem

The present disclosure has been devised to solve the above problems, and an objective of the present disclosure is to efficiently transmit signals or power with low loss between a transmission line of the multilayer PCB and a waveguide through a proposed transition structure of a transmission line of the multilayer PCB and a waveguide.

Another objective of the present disclosure is to provide a very simple, inexpensive, and easy-to-manufacture transition structure through which signals may be effectively transmitted by reducing transition loss within a transmission frequency band of high frequency signals transmitted between a transmission line of the multilayer PCB and a waveguide.

Yet another objective of the present disclosure is to efficiently transmit signals or power with low loss between a waveguide and a transmission line of a multilayer PCB composed of dielectric layers made of heterogeneous materials.

Still another objective of the present disclosure is to provide a simple and easy-to-manufacture transition structure capable of effectively transmitting signals by reducing transition loss within a frequency band of signals to be transmitted when the signals are transmitted between a waveguide and a transmission line of a multilayer PCB composed of dielectric layers made of heterogeneous materials.

In a transition structure of a transmission line of the multilayer PCB and a waveguide, still another objective of the present disclosure is to transfer signals with high efficiency by reducing loss of signals transmitted by a via hole between a first ground layer and a bottom ground layer of the transmission line in order to correspond to a connection part of the transmission line and the waveguide.

In a transition structure of a transmission line of the multilayer PCB and a waveguide, still another objective of the present disclosure is to provide the transition structure between the transmission line of the multilayer PCB and the waveguide for efficiently transferring signals with low loss, the signals being transmitted by via holes between a first ground layer and a bottom ground layer of the transmission line corresponding to a connection part of a transmission line and a waveguide.

Still another objective of the present disclosure is to provide a transition structure between a multilayer PCB and a waveguide for effectively transferring signals toward an exit of the waveguide in a way where via holes may be arranged in one or more rows so as to correspond to an inlet area of the waveguide, and is arranged in a row or in a zigzag in two or more rows in order to reduce loss characteristics of the transferred signals of a frequency band.

Still another objective of the present disclosure is to provide a transition structure between a multilayer PCB and a waveguide for effectively transferring signals toward an exit of the waveguide by arranging a single via pillar instead of a plurality of via holes in order to reduce loss characteristics of the transferred signals of a frequency band.

The objectives of an exemplary embodiment of the present disclosure is not limited to the above-mentioned objectives, and other different objectives not mentioned herein will be clearly understood by those skilled in the art from the following description.

### Technical Solution

According to the features for achieving the above objectives, the present disclosure provides a transition structure between a transmission line of a multilayer PCB and a waveguide, the transition structure including: the waveguide comprising an interior space on one side thereof and having an inlet for accommodating a part of a stripline;

the transmission line including a first ground layer of the multilayer PCB composed of at least two or more dielectric layers;

the stripline extending from the transmission line and protruding into the waveguide through the inlet of the waveguide; and

a single via hole or a plurality of via holes formed between the first ground layer and a bottommost ground layer,

wherein each via hole is positioned at the inlet of the waveguide.

In addition, a dielectric layer including the stripline may be connected from a dielectric layer of the transmission line.

In addition, the strip line may be spaced apart from a backshort of the waveguide by a predetermined distance.

In addition, each via hole may be arranged at a last end of the inlet of the waveguide.

In addition, each via hole may be installed as a single via hole array or a plurality of via hole arrays

In addition, each via hole may be installed by arranging in a zigzag vertically or horizontally.

In addition, a spacing between each via hole may be arranged in a range of 10 to 500 μm.

In addition, a via pillar may be used instead of each via hole.

In addition, the dielectric layers constituting the multilayer PCB may be composed of at least one or more different dielectrics.

In addition, a dielectric dissipation factor of a topmost dielectric layer constituting the multilayer PCB may be lower than dielectric dissipation factors of other dielectric layers other than the topmost dielectric layer.

### Advantageous Effects

According to the transition structure between the waveguide and the transmission line of the multilayer PCB according to the present disclosure, there is provided an effect that signals are transferred with high efficiency by reducing the loss of signals transmitted from the transmission line of the multilayer PCB to the waveguide by means of one or more via holes between the ground layers of the multilayer PCB installed to correspond to a waveguide inlet area adjacent to the transmission line protruding into the waveguide thereto.

In addition, there is provided an effect that the plurality of via holes between the ground layers of the multilayer PCB is arranged in one or more rows or is arranged in two or more rows in a zigzag vertically or horizontally, or one via pillar is arranged, so as to reduce the loss of transmission signals, thereby transferring the signals with high efficiency.

### DESCRIPTION OF DRAWINGS

FIGS. 1(a) and 1(b) are respectively a cross-sectional view and a plan view illustrating an example of applying a multilayer PCB to a transition structure between a transmission line of a PCB and a waveguide according to a conventional disclosure.

FIGS. 2(a) and 2(b) are respectively a cross-sectional view and a plan view illustrating a transition structure between a transmission line of the multilayer PCB and a waveguide according to an exemplary embodiment of the present disclosure, and FIG. 2(c) is a plan view illustrating a first ground layer b-b′ in the transition structure between the transmission line of the multilayer PCB and the waveguide according to the exemplary embodiment of the present disclosure.

FIGS. 3(a) and 3(b) are respectively a cross-sectional and a plan view illustrating a transition structure between a transmission line of a multilayer PCB and a waveguide according to another exemplary embodiment of the present disclosure, and FIG. 3(c) is a plan view in the first ground layer b-b′ in the transition structure between the transmission line of the multilayer PCB and the waveguide according to the exemplary embodiment of the present disclosure.

FIG. 4 is a view illustrating a transition structure between a transmission line of a multilayer PCB and a waveguide according to yet another exemplary embodiment of the present disclosure.

FIG. 5 is a view illustrating a transition structure between a transmission line of a multilayer PCB and a waveguide according to still another exemplary embodiment of the present disclosure.

FIG. 6 is a view illustrating a transition structure between a transmission line of a multilayer PCB and a waveguide according to still another exemplary embodiment of the present disclosure.

FIG. 7 is a view illustrating a transition structure between a transmission line of a multilayer PCB and a waveguide according to still another exemplary embodiment of the present disclosure.

FIG. 8 is a view illustrating a transition structure between a transmission line of a multilayer PCB and a waveguide according to still another exemplary embodiment of the present disclosure.

FIG. 9 is a set of signal transmission characteristic graphs respectively obtained by the transition structures between the transmission lines of the multilayer PCBs and the waveguides according to the present disclosure.

### MODE FOR INVENTION

Hereinafter, the objectives, other objectives, features and advantages of the present disclosure will be readily understood through the following preferred exemplary embodiments in conjunction with the accompanying drawings. However, the present disclosure is not limited to the exemplary embodiments described herein and may be embodied in other forms.

Rather, the exemplary embodiments introduced herein are provided so that the disclosed subject matter may be thorough and complete, and that the spirit of the present disclosure may be sufficiently conveyed to those skilled in the art.

The exemplary embodiments described and illustrated herein also include complementary exemplary embodiments thereof.

In this specification, the singular form also includes the plural form unless otherwise specified in the phrase. As used herein, “comprises” and/or “comprising” does not exclude the presence or addition of one or more other components in addition to the mentioned components.

Hereinafter, the present disclosure will be described in detail with reference to the drawings. In describing the specific exemplary embodiments below, various characteristic contents have been prepared to more specifically explain the disclosure and help understanding. However, a reader having enough knowledge in this field to understand the present disclosure may recognize that the present disclosure may be used without these various specific details. In some cases, it is mentioned in advance that in describing the present disclosure, parts that are commonly known and not largely related to the present disclosure are not described in order to avoid confusion in explaining the present disclosure.

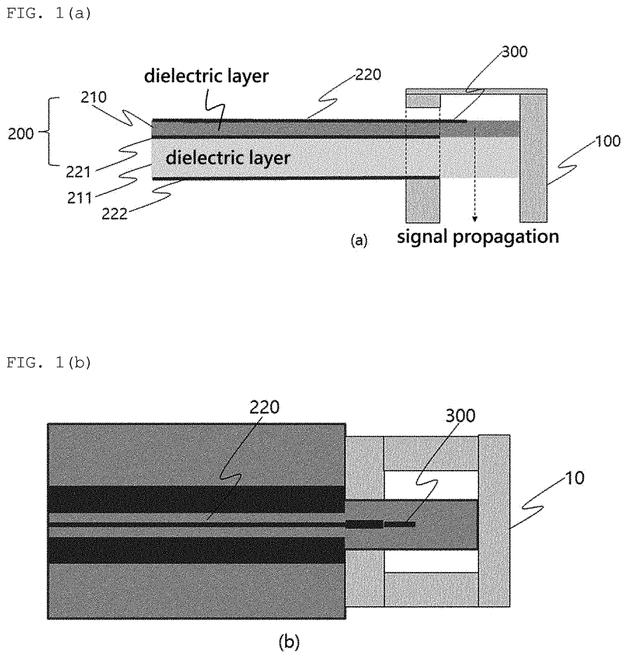

FIG. 1 is a view illustrating a multilayer PCB applied to a transition structure between a transmission line and a waveguide according to a conventional disclosure. The transmission line of the PCB is connected from an integrated circuit (not shown) to transmit input/output signals, and transmit the signals in a form of CPWGs, microstrips, etc.

Such a transmission line 200 is composed of a dielectric layer 210, a metal layer 220 for signal transmission on an upper surface of the dielectric layers 210, and a metal layer 221 as a ground layer on a lower surface of the dielectric layer 210 corresponding to the metal layer 220. At a last end of the transmission line, a stripline 300 having no ground layer on a bottom of the dielectric layer protrudes and is positioned inside a waveguide 100, so as to be coupled thereto. Meanwhile, a metal layer 222 for a ground layer of the entire PCB is also formed on a lowermost bottom surface of the entire dielectric layers 210 and 211 constituting the multilayer PCB, that is, a bottom surface of the lowermost dielectric layer 211.

For impedance matching to reduce loss, each of these transmission lines such as CPWGs and microstrips has a different width of a metal layer that transmits signals, and accordingly the stripline protruding into the waveguide should also be planned with a design and a size, which reduce the loss.

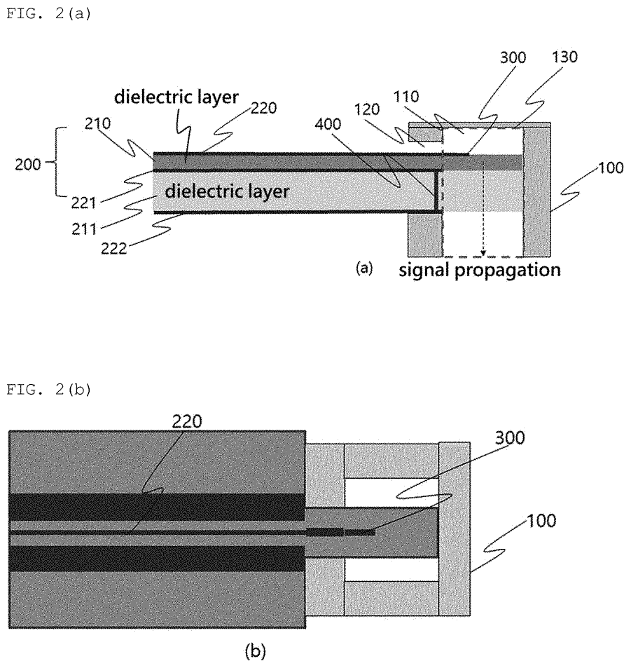

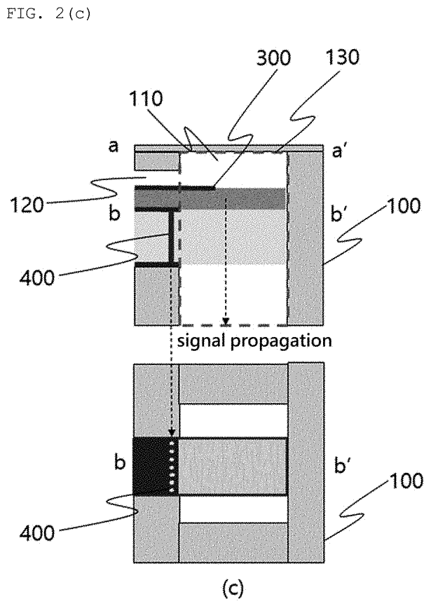

FIG. 2 is a view illustrating a transition structure between a transmission line of a multilayer PCB and a waveguide according to the exemplary embodiment of the present disclosure. FIG. 2(a) is a cross-sectional view according to the exemplary embodiment of the present disclosure, and FIG. 2(b) is a plan view illustrating a structure in a state in which an upper cover a-a′ of the waveguide on the view is removed for description. FIG. 2(c) is a plan view illustrating a first ground layer b-b′ to indicate a structure of via holes according to the exemplary embodiment of the present disclosure.

The transition structure between the transmission line of the multilayer PCB and the waveguide according to the exemplary embodiment of the present disclosure is configured to include: a waveguide 100 including an interior space 110 on one side thereof and having an inlet 120 configured to accommodate a part of a stripline 300; a transmission line 200 including a first ground layer 221 of the multilayer PCB composed of at least two or more dielectric layers 210 and 211; the stripline 300 extending from the transmission line 200 and protruding into the waveguide 100 through the inlet 120 of the waveguide 100; and a single via hole or a plurality of via holes 400 formed between the first ground layer 221 and a lowermost ground layer 222, wherein each via hole 400 is positioned at the inlet 120 of the waveguide 100.

More specifically, the transmission line 200 of the PCB is connected from an integrated circuit (not shown) to transmit input/output signals, and transmit the signals in a form of CPWG, microstrip, or the like. Such CPWG or microstrip is described as a general form of the configuration, but is not limited thereto.

Such a transmission line 200 is configured in a way that a partial area 300 extending and protruding toward the inside of the waveguide 100 is coupled to the waveguide 100, and as such, signals are transmitted to the inside of the waveguide 100 by means of the coupling of the stripline 300 that is the last end of the transmission line protruding into the waveguide 100. The strip line is formed to be spaced apart from an inner surface of an upper cover a-a′ of the waveguide, that is, a backshort 130 of the waveguide, by a predetermined space. Such a separation space becomes an important design factor of a transition structure in order to reduce transition loss.

In addition, since the transmission line and the stripline extending and protruding therefrom may be manufactured at the same time when the same PCB, that is, the same dielectric substrate layer is used, the transmission line and the stripline may be easily manufactured while reducing the cost.

For impedance matching to reduce loss, each of these transmission lines such as CPWG and microstrip has a different width of a metal layer 220 transmitting signals, and accordingly, the stripline 300 protruding into the waveguide 100 should also be planned with a design and a size, which reduce the loss.

In this case, in an area adjacent to the stripline 300 protruding from the transmission line 200 of the multilayer PCB, via holes 400 are formed between the ground layers of the transmission line of the multilayer PCB, that is, a first ground layer 221 from the top of the multilayer PCB and a bottommost ground layer 222 formed on the bottom surface of the multilayer PCB, so as to serve as a via fence, thereby reducing signal loss due to the second dielectric layer and effectively propagating signals toward an output unit of the waveguide 100.

Here, the via hole refers to a structure that electrically connects metal layers in multilayer wiring to each other by means of a hole formed to have a circular cross-section and provided with a metal layer coated on a side surface thereof in a vertical direction therein for electrical connections between the metal layers in the multilayer wiring in a common PCB process. In this way, only the side surface of the interior of the via hole is composed of the metal layer to electrically connect upper and lower metal layers to each other, but when necessary, the via hole may also be used by filling the inside thereof with metal. Such via holes are manufactured using in the common PCB manufacturing process, and is formed in a circular shape having a size of a diameter of several tens to hundreds of micrometers in the manufacturing process. Naturally, the via holes may also be manufacturable for use in a size greater than or equal to the said size, or smaller than or equal to the said size according to the manufacturing process. In addition, it is noted that as for the shape of the via holes, various shapes easy to be manufactured, the shapes having not only a circular cross section and the like, but also a rectangular cross section may also be usable.

These via holes 400 may be arranged in a line as shown in FIG. 2(c) in order to enhance the effect of reducing loss in a transition structure.

Here, it is noted that the arrangement means that the plurality of via holes 400 is aligned in one direction.

A spacing between via holes 400 may also be a spacing of several tens to hundreds of pm depending on the manufacturing process. In particular, when the spacing of the via holes becomes 10 to 500 μm corresponding to a frequency domain of the ultra-high frequencies used and transmitted in such ultra-high frequency circuits, the effect caused by the spacing of the via holes may be increased.

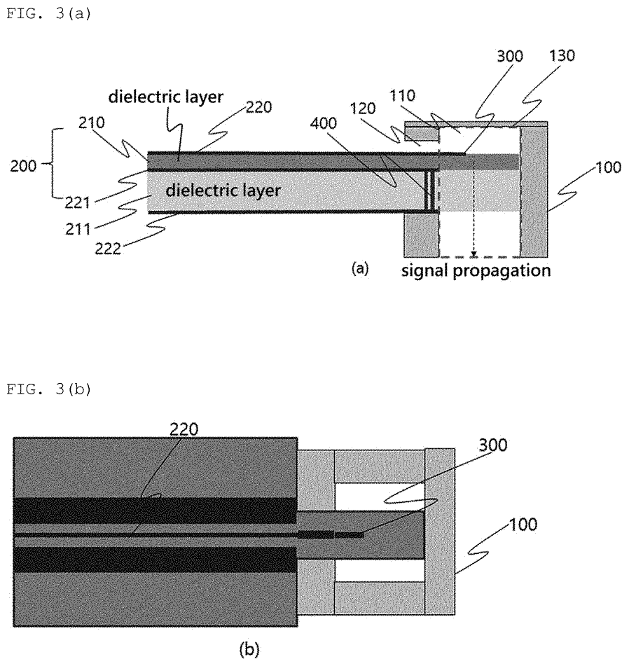

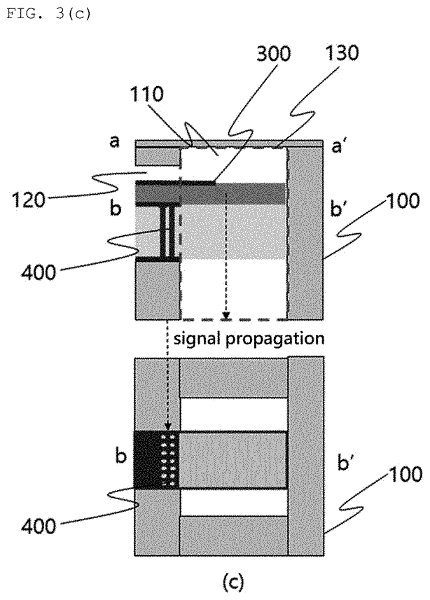

FIGS. 3(a) and 3(b) are respectively a cross-sectional view and a plan view illustrating a transition structure between a transmission line of a multilayer PCB and a waveguide according to another exemplary embodiment of the present disclosure. FIG. 3(c) is a plan view in a first ground layer b-b′ in the transition structure between the transmission line of the multilayer PCB and the waveguide according to the exemplary embodiment of the present disclosure.

The configuration of the transition structure of the transmission line of the multilayer PCB and the waveguide is the same as shown in FIG. 2, and shown in FIG. 3(c), this view illustrates a form in which via holes 400 formed between the ground layer 221 of the transmission line and a ground layer 222 of a bottom surface of the PCB, that is, a first ground layer 221 and a bottommost ground layer 222 of the multilayer PCB, are arranged in two rows. By arranging the via holes 400 in two rows in this way, it is possible to increase the effect of reducing signal loss. As described above, the spacing between the first and second rows of the via holes may be tens to hundreds of μm depending on the manufacturing process.

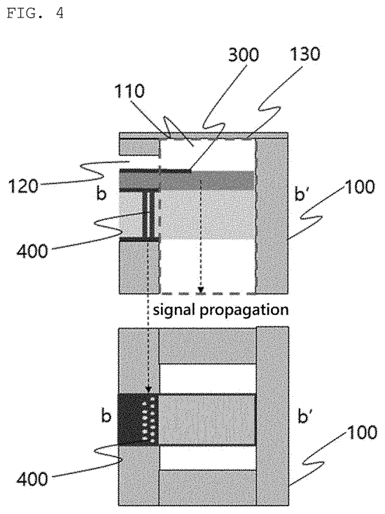

FIG. 4 is a view illustrating a transition structure between a transmission line of a multilayer PCB and a waveguide according to yet another exemplary embodiment of the present disclosure. As previously described in FIG. 3, two rows of via holes 400 formed between a corresponding ground layer of the transmission line and a ground layer of a bottom surface of the PCB, that is, a first ground layer 221 and a bottommost ground layer 222 of the multilayer PCB may be arranged in a zigzag on a horizontal side surface, so as to increase the effect thereof.

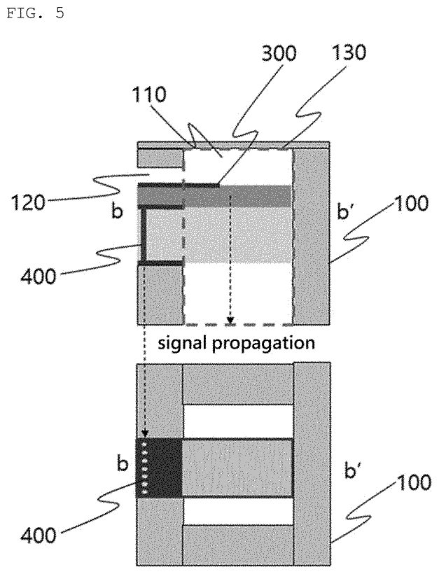

FIG. 5 is a view illustrating a transition structure between a transmission line of a multilayer PCB and a waveguide according to still another exemplary embodiment of the present disclosure. This view illustrates a case where via holes 400 formed between a corresponding ground layer of the transmission line and a ground layer of a bottom surface of the PCB, that is, a first ground layer 221 and a bottommost ground layer 222 of the multilayer PCB is arranged in a first entrance area further away from a last end of an inlet area, rather than the last end of the waveguide inlet area formed for the transmission line 200 to enter the inside of the waveguide 100. In this case as well, by means of such via holes 400, an effect of increasing the signal transfer efficiency may be achieved by reducing signal loss. However, the effect may be lower than that in the case of designing the via holes according to FIGS. 2 to 4 described above (i.e., the case where a via hole or via holes in arrangement are positioned at the last end of the inlet area), so the adjustment of the frequency band for transmitting the signals may be required.

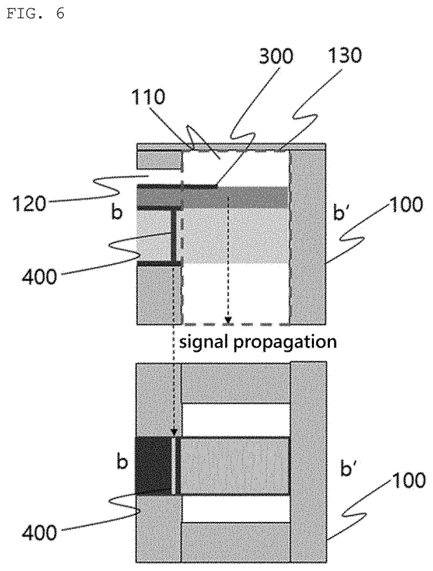

FIG. 6 is a view illustrating a transition structure between a transmission line of a multilayer PCB and a waveguide according to still another exemplary embodiment of the present disclosure. A via hole 400 formed between a ground layer of the transmission line and a ground layer of a bottom surface of the PCB, that is, a first ground layer 221 and a bottommost ground layer 222 of the multilayer PCB, is formed as a single via pillar, rather than formed in a form of an array. In this case as well, as in the case of using the via holes arranged in one or two rows, the via hole serves as a via fence and may effectively transfer signals by reducing transition loss.

Here, it should be noted that the via pillar means a structure having a predetermined area, not the shape of a via hole 400.

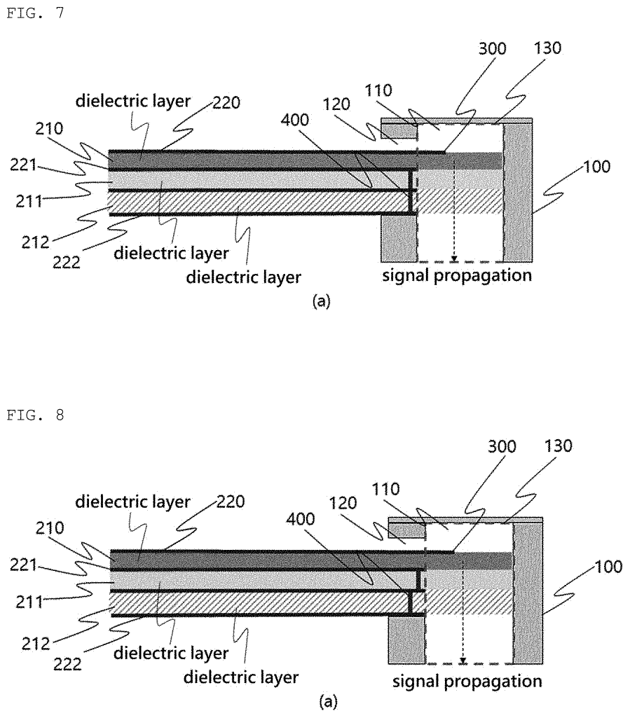

FIG. 7 is a view illustrating a transition structure between a transmission line of a multilayer PCB and a waveguide according to still another exemplary embodiment of the present disclosure. This view illustrates a case of using a PCB having three dielectric layers 210, 211, and 212, other than a multilayer PCB having two dielectric layers.

Via holes 400 are similarly applied between a corresponding ground layer of the transmission line and a ground layer of a bottom surface, that is, a first ground layer 221 and a third bottommost ground layer 222 of the multilayer PCB, so as to reduce transition loss due to PCB substrate layers, thereby effectively transmit signals.

As described above, these dielectric layers 210, 211, and 212 may all use the same dielectric material or, when necessary, may use heterogeneous dielectric materials by bonding heterogeneous materials. In particular, it is preferable to apply a dielectric layer, made of a material such as Teflon having low dielectric loss, to a first layer at the top, the first layer playing an important signal transmission role. In the case of the multilayer PCB in which heterogeneous dielectric materials are bonded in this way, some layers have particularly low dielectric loss (i.e., loss tangent), and a low-cost layer with good mechanical properties may be applied to a lower layer.

In addition, the dielectric layers constituting the multilayer PCB presented in the present disclosure may be composed of at least one or more different dielectrics, but it is preferable to make a dielectric dissipation factor of the top dielectric layer constituting the multilayer PCB to be low compared to dielectric dissipation factors of other dielectric layers other than the topmost dielectric layer.

In addition, although the multilayer PCB having three dielectric layers 210, 211, and 212 has been illustrated and described in FIG. 7, the same transition structure may be applied to a transition structure of a multilayer PCB having three or more layers. Via holes 400 are similarly applied between a corresponding ground layer of a transmission line and a ground layer of a bottom surface of the PCB, that is, a first ground layer 221 and a bottommost ground layer 222 of the multilayer PCB, so as to reduce transition loss due to the substrate layers of the PCB, thereby effectively transmitting signals.

FIG. 8 is a view illustrating a transition structure between a transmission line of a multilayer PCB and a waveguide according to still another exemplary embodiment of the present disclosure. In a multilayer PCB having three dielectric layers 210, 211, and 212, via holes 400 are arranged and applied, in a zigzag in a vertical direction, between a corresponding ground layer of the transmission line and a ground layer of a bottom surface of the PCB, that is, a first ground layer 221 and a third bottommost ground layer 222 of the multilayer PCB, so as to reduce transition loss due to the substrate layers of the PCB, thereby effectively transmit signals.

In addition, although the multilayer PCB having the three dielectric layers 210, 211, and 212 has been illustrated and described in FIG. 8, the same transition structure may be applied to a transition structure of a multilayer PCB having three or more layers. Via holes 400 are similarly applied, in a zigzag in the vertical direction, between a corresponding ground layer of the transmission line and a ground layer of a bottom surface of the PCB, that is, a first ground layer 221 of the multilayer PCB and a bottommost ground layer 222 of the multilayer PCB, so as to reduce transition loss due to the substrate layers of the PCB, thereby effectively transmit signals.

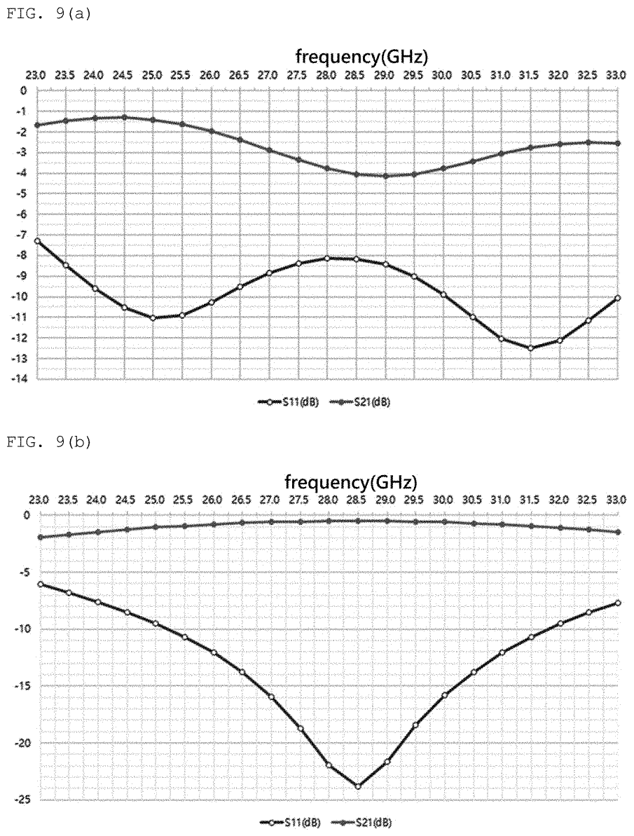

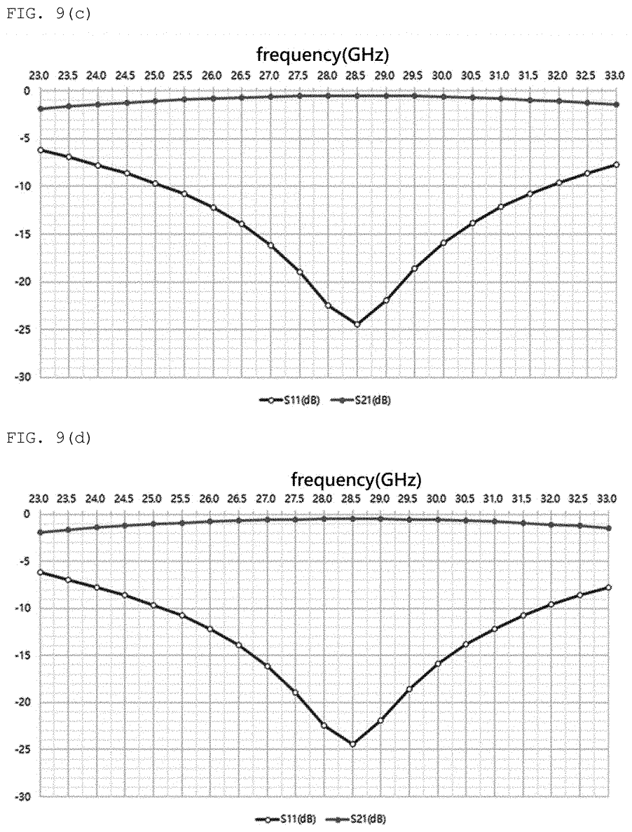

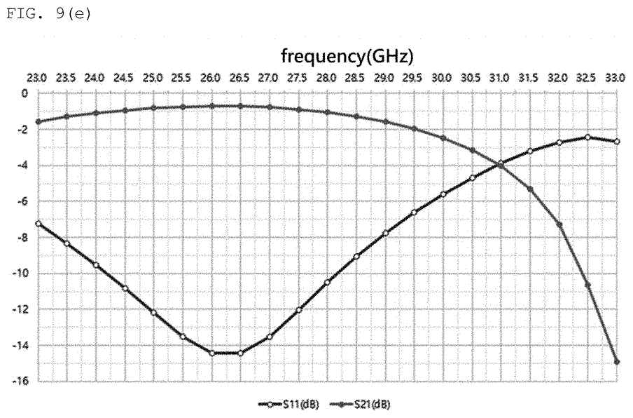

FIG. 9 is a set of signal transmission characteristic graphs respectively obtained by the transition structures between the transmission lines of the multilayer PCBs and the waveguides according to the present disclosure. These graphs illustrate design structures for transmitting frequencies of around 28 GHz band, and the waveguide is also applied with WR28 specifications having a cross section of 3.556 mm×7.112 mm that transmits the frequencies of the frequency band.

In a case of FIG. 9(a), this view illustrates a graph that simulates signal transmission characteristics for a transition structure in which a multilayer PCB is applied to a configuration of the conventional disclosure of FIG. 1 described above. In the 28 GHz band, a return loss S11 characteristic is significantly bad, and an insertion loss S21 characteristic is also high at −4 dB or less.

In the case of FIG. 9(b), this view illustrates a signal transmission characteristic graph to which the first exemplary embodiment of FIG. 2 is applied by using the same multilayer PCB structure. In the 28 GHz band, the return loss S11 is about −24 dB, and the insertion loss S21 is −1 dB or less, so the loss is significantly small compared to the loss of the case of FIG. 9(a), whereby signals are effectively transferred in a target frequency band.

In the case of FIG. 9(c), this view illustrates a signal transfer characteristic graph according to the exemplary embodiment of FIG. 3. The return loss and the insertion loss are improved compared to the case of FIG. 9(b). Even in this case, the loss is significantly small compared to the loss in the conventional case, whereby signals are transferred very effectively in the target frequency band.

In the case of FIG. 9(d), this view illustrates a signal transfer characteristic graph according to the exemplary embodiment of FIG. 4. The insertion loss S21 is −1 dB or less, so the loss is significantly small compared to the case of FIG. 9(a), whereby signals are effectively transferred in the target frequency band.

In the case of FIG. 9(e), this view illustrates a signal transfer characteristic graph according to the exemplary embodiment of FIG. 5. The return loss S11 is about −14 dB, so a pass frequency band is also shifted. Although the transmission characteristics are improved compared to that of FIG. 9(a), the transmission characteristics are not good compared to the previous exemplary embodiments, and the frequency band is also shifted. Among the transition structures, it may be confirmed that the previous exemplary embodiments in which the via holes are applied close to the inlet area where the last end of the stripline of the transmission line of the multilayer PCB protrudes into the waveguide are more effective. Naturally, even in the case of the exemplary embodiment of FIG. 5, the signal transmission frequency band may be redesigned and applied to a transition structure of a transmission line of a multilayer PCB and a waveguide.

[symbol]

The exemplary embodiments described in the present specification and the configurations shown in the drawings are only the most preferred exemplary embodiments of the present disclosure, and do not represent all the technical ideas of the present disclosure, and accordingly, it should be appreciated that there may be equivalents and modifications at the time when the present application is filed.

1. A transition structure between a transmission line of a multilayer PCB and a waveguide, the transition structure comprising:
the waveguide comprising an interior space on one side thereof and having an inlet for accommodating a part of a stripline;
the transmission line comprising the stripline and at least two ground layers below the stripline of the multilayer PCB composed of at least two or more dielectric layers;
the stripline extending from the transmission line and protruding into the waveguide through the inlet of the waveguide; and
a single via hole or a plurality of via holes formed between the at least two ground layers,
wherein each via hole is positioned at the inlet of the waveguide.

2. The transmission line of claim 1, wherein a dielectric layer comprising the stripline is connected from a dielectric layer of the transmission line.

3. The transition structure of claim 1, wherein the stripline is spaced apart from a backshort of the waveguide by a predetermined distance.

4. The transition structure of claim 1, wherein each via hole is arranged at a last end of the inlet of the waveguide.

5. The transition structure of claim 1, wherein each via hole is installed as a single via hole array or a plurality of via hole arrays

6. The transition structure of claim 1, wherein each via hole is installed by arranging in a zigzag vertically or horizontally.

7. The transition structure of claim 1, wherein a spacing between each via hole is arranged in a range of 10 to 500 μm.

8. The transition structure of claim 1, wherein a via pillar is used instead of each via hole.

9. The transition structure of claim 1, wherein the dielectric layers constituting the multilayer PCB are composed of at least one or more different dielectrics.

10. The transition structure of claim 1, wherein a dielectric dissipation factor of a topmost dielectric layer constituting the multilayer PCB is lower than dielectric dissipation factors of other dielectric layers other than the topmost dielectric layer.
